(19) United States
(12) Patent Application Publication
(10) Pub. No.: US 2017/0168313 A1
(43) Pub. Date: Jun. 15, 2017

(54) LASER LIGHT SOURCE DEVICE AND IMAGE PROJECTION DEVICE

(71) Applicant: USHIO DENKI KABUSHIKI KAISHA, Tokyo (JP)

(72) Inventors: Hirotaka YAMADA, Himeji-shi (JP); Kengo MORIYASU, Himeji-shi (JP)

(73) Assignee: USHIO DENKI KABUSHIKI KAISHA, Tokyo (JP)

(21) Appl. No.: 15/117,098

(22) PCT Filed: Feb. 5, 2015
(86) PCT No.: PCT/JP2015/053237

§ 371 Date: Aug. 5, 2016

(30) Foreign Application Priority Data
Feb. 12, 2014 (JP) 2014-024261

(51) Int. Cl. G02B 27/48; H01S 5/00; G03B 21/20; H01S 5/40; G02B 19/00; G02B 27/12

(52) U.S. Cl. CPC G02B 27/48; G02B 19/0057; G02B 27/123; G03B 21/2013; G03B 21/2033; G03B 21/208; H01S 5/4012; H01S 5/0071

(57) ABSTRACT

An image projection device is provided with at least one laser light source device and uses a light beam exited from the laser light source device as projection light. A laser light source device is provided with a plurality of light source units from which laser beams exit, the plurality of light source units are divided into a plurality of laser light source groups based on magnitudes of angles at which optical axes of the laser beams are incident on the incident surface. As the incident angles of the laser beams from the laser light source group are larger, an average value of convergence angle and/or divergence angle of the laser beams in the laser light source group becomes smaller when the laser beams are incident on the incident surface.

### TECHNICAL FIELD

The present invention relates to a laser light source device provided with a plurality of laser light sources exiting laser beams and further relates to an image projection device provided with a laser light source device.

### BACKGROUND ART

In the prior art, as a laser light source device, there has been known a laser light source device in which laser beams exited from a plurality of laser light sources are incident on an optical fiber and so on (for example, Patent Document 1). In addition, there has been known a technique in which light exited from this laser light source device is used as a light source of a light source device for light exposure, a projector, or the like. In this technique, noise with the intensity of light, which is called speckle noise, occurs on a laser beam irradiation surface or on the retinas of an observer.

Thus, Patent Document 1 proposes the laser light source device in which, in order to reduce speckle noise, at least one laser light sources exits light having a wavelength different from that of light exited from other laser light sources. However, in the laser light source device according to Patent Document 1, since there is a limit to a usable wavelength range, there is a problem that a sufficient reduction in speckle noise (also referred to as a “despeckle effect” or “reduction in speckle contrast”) cannot be achieved.

### PRIOR ART DOCUMENTS

### Patent Documents

Patent Document 1: JP-A-2004-146793

### SUMMARY OF THE INVENTION

### Problems to be Solved by the Invention

Accordingly, in view of the above circumstances, an object of the present invention is to provide a laser light source device and an image projection device which can achieve a sufficient reduction in speckle noise.

### Means for Solving the Problems

According to the present invention, there is provided a laser light source device, which includes:

a plurality of light source units from which laser beams exit; and

a light guide body having an incident surface on which the laser beams exited from the plurality of light source units are incident,

wherein the plurality of light source units are divided into a plurality of laser light source groups based on magnitudes of angles at which optical axes of the laser beams are incident on the incident surface; and

as the incident angles of the laser beams from the laser light source group are larger, an average value of convergence angle and/or divergence angle of the laser beams in the laser light source group becomes smaller when the laser beams are incident on the incident surface.

Also, there is provided a laser light source device, which includes:

a plurality of light source units from which laser beams exit; and

an optical system on which the laser beams exited from the plurality of light source units are incident and which exits the laser beams toward an incident surface of a light guide body,

wherein the plurality of light source units are divided into a plurality of laser light source groups based on magnitudes of angles at which optical axes of the laser beams are incident on the incident surface; and

the light source unit and the optical system are configured such that as the incident angles of the laser beams from the laser light source group are larger, an average value of convergence angle and/or divergence angle of the laser beams in the laser light source group becomes smaller when the laser beams are incident on the incident surface.

According to the laser light source device of the present invention, a plurality of laser light source groups are provided with a light source unit from which a laser beam exits toward an incident surface of a light guide body. The plurality of laser light source groups are divided for each magnitude of an incident angle to an incident surface of an optical axis of a laser beam exited from the light source unit.

Since an optical path length in a light guide body increases as the incident angle of a laser beam is larger, in diverging laser beam, an optical path length difference between an optical axis portion and another portion increases, for example. In the same incident angle, as the convergence angle or the divergence angle of a laser beam is larger when the laser beam is incident on an incident surface, the optical path length difference between the optical axis portion and another portion in the laser beam increases, for example. When the optical path length difference between the optical axis portion and another portion in the laser beam thus increases, coherence is lowered. Consequently, speckle noise is reduced.

Thus, in the laser light source device according to the present invention, as the incident angles of laser beams from a laser light source group are larger, an average value of the convergence angle and/or the divergence angle of the laser beams in the laser light source group becomes smaller when the laser beams are incident on an incident surface. Consequently, in a laser beam in which the convergence angle or the divergence angle is small, the optical path length in the light guide body is increased by increasing the incident angle, and therefore, for example, the optical path length difference between the optical axis portion and another portion in the laser beam is ensured. Accordingly, since coherence of a laser beam in the entire device is lowered, speckle noise in the entire device is reduced.

Also, the laser light source device according to the present invention may have a configuration in which:

as the incident angle of the laser beam from the light source unit is larger, the convergence angle or the divergence angle of the laser beam in the light source unit becomes smaller when the laser beam is incident on the incident surface.

According to such a constitution, as the incident angle of a laser beam from the light source unit is larger, the convergence angle or the divergence angle of the laser beam in the light source unit becomes smaller when the laser beam is incident on an incident surface. Namely, as the convergence angle or the divergence angle of the laser beam is smaller, the incident angle of the laser beam becomes larger. Accordingly, since the coherence of a laser beam in the entire device is effectively lowered, the speckle noise in the entire device is effectively reduced.

Also, there is provided an image projection device, which includes at least one the laser light source device and uses a light beam exited from the laser light source device as projection light.

### Effect of the Invention

As described above, the present invention provides such an excellent effect that a sufficient reduction in speckle noise can be achieved.

### BRIEF DESCRIPTION OF THE DRAWINGS

FIG. 1 is a schematic configuration diagram of an image projection device according to one embodiment of the present invention.

FIG. 2 is a schematic configuration diagram of a laser light source device according to the same embodiment.

FIG. 3 is a view for explaining an incident pattern of light being incident on an optical system according to the same embodiment.

FIG. 4 is a view for explaining an incidence angle of light on an incident surface of a light guide body according to the same embodiment.

FIG. 5 is a view for explaining an optical path length in the light guide body according to the embodiment.

FIG. 6 is a view for explaining an optical path length in the light guide body according to the embodiment.

FIG. 7 is a view for explaining an optical path length in the light guide body according to the embodiment.

FIG. 8 is a view for explaining an optical path length in the light guide body according to the embodiment.

FIG. 9 is a schematic configuration diagram of a device for verifying the effect of the present invention.

FIG. 10 is a view for explaining the verification result on the effect of the present invention.

FIG. 11 is a view for explaining an incident pattern of light being incident on an optical system according to another embodiment of the present invention.

### MODE FOR CARRYING OUT THE INVENTION

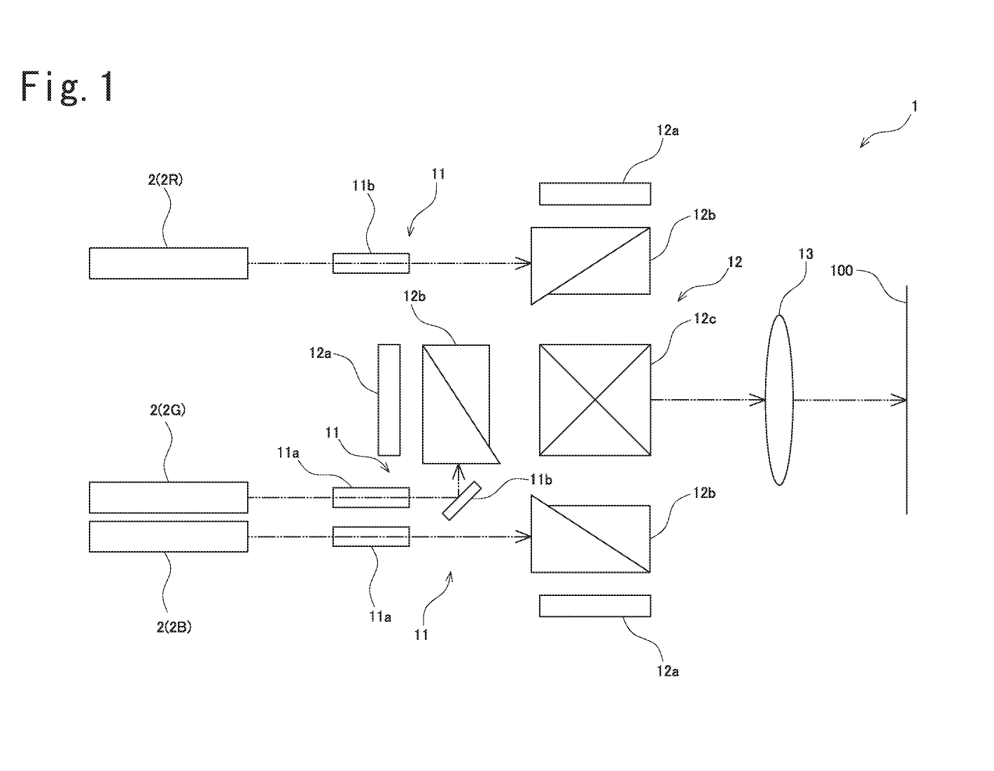

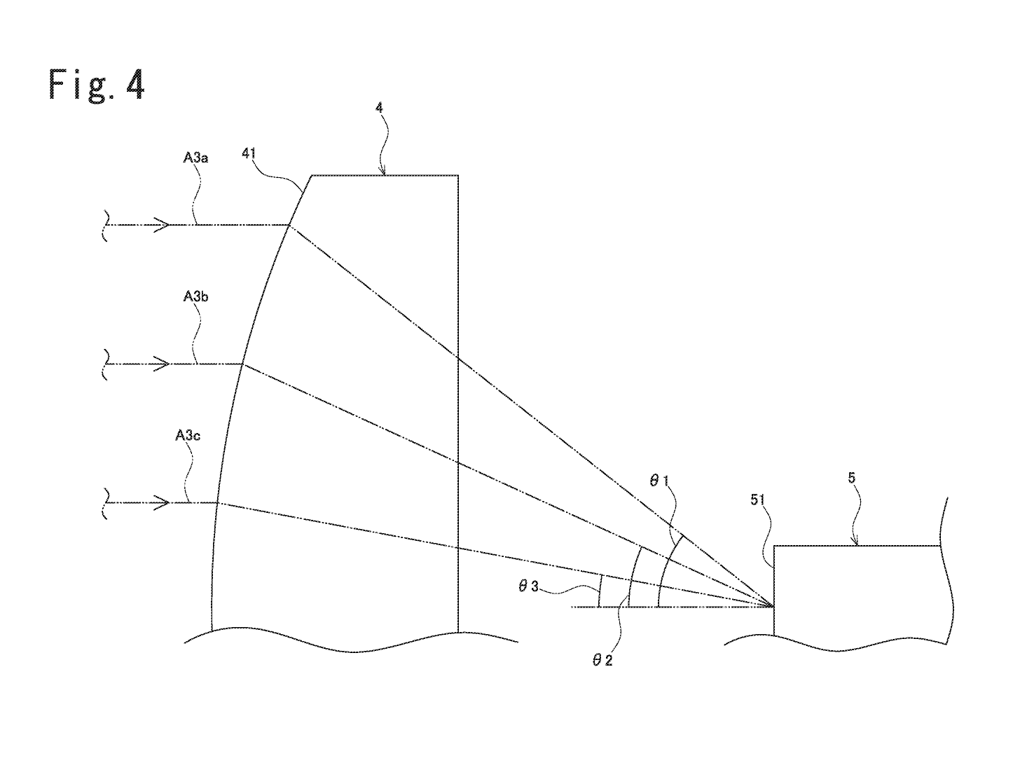

Hereinafter, an embodiment in a laser light source device and an image projection device according to the present invention will be described with reference to FIGS. 1 to 10. A dimensional ratio of the drawing does not necessarily coincide with an actual dimensional ratio in each of the drawings.

As shown in FIG. 1, an image projection device 1 according to this embodiment is provided with a plurality of (three in this embodiment) laser light source devices 2 (2R, 2G, and 2B) from which different colors of light exit and a light source side optical system 11 on which a laser beam exited from the laser light source device 2 is incident. The image projection device 1 is provided with an image optical system 12 on which a laser beam exited from the light source side optical system 11 is incident for generating an optical image and a projection optical system (for example, a projection lens) 13 on which the optical image (laser beam) exited from the image optical system 12 is incident to be projected on a screen 100.

To achieve uniformity of illuminance of an irradiation surface on which an optical image is projected, the light source side optical system 11 is provided with an integrator optical system 11a such as a rod integrator and a reflection mirror 11b reflecting a laser beam exited from the laser light source device 2G. Although not illustrated, the light source side optical system 11 is provided with a lens for imaging an exit surface of the integrator optical system 11a in the image optical system 12 (specifically, an incident surface of a space modulation element 12a).

The image optical system 12 is provided with the space modulation element 12a which modulates light exited from the light source side optical system 11 to form an optical image, a total reflection prism 12b, and a dichroic prism 12c. In this embodiment, each of the space modulation elements 12a is a digital micromirror device. The space modulation element 12a may be a transmission type liquid crystal element or a reflection type liquid crystal element.

The laser light source device 2 is provided with a first laser light source device 2R exiting a laser beam of a first color (for example, red), a second laser light source device 2G exiting a laser beam of a second color (for example, green), and a third laser light source device 2B exiting a laser beam of a third color (for example, blue).

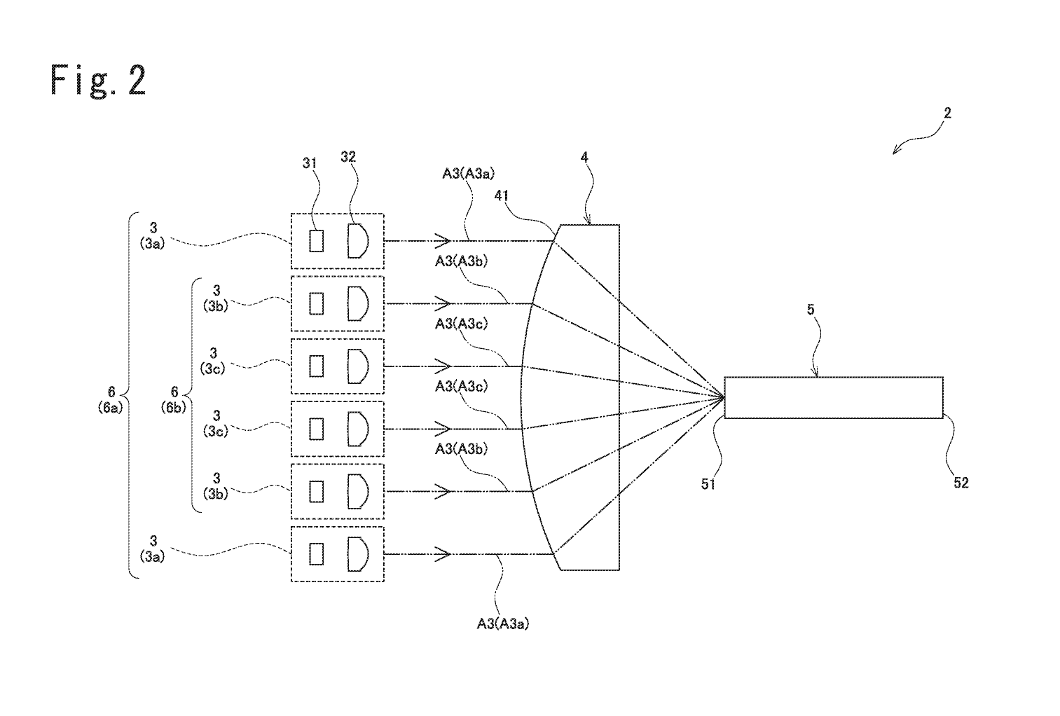

As shown in FIG. 2, the laser light source device 2 according to this embodiment is provided with light source units 3 from which laser beams exit, an optical system 4 on which laser beams exited from the light source units 3 are incident, and a light guide body 5 having an incident surface 51 on which laser beams exited from the optical system 4 are incident. In the laser light source device 2, light exited from the light guide body 5 is incident on the light source side optical system 11.

The light source unit 3 is provided with a semiconductor laser 31 from which a laser beam exits and a collimate lens 32 converting a laser beam exited from the semiconductor laser 31 into substantially collimated light (slightly diverging light). The light source units 3 are disposed such that the optical axes A3 of laser beams exited from the light source units 3 are parallel to each other when the laser beams are incident on at least the optical system 4. In addition, the light source units 3 are disposed such that the optical axes A3 of laser beams exited from the light source units 3 are located at different positions on an optical incident surface 41 of the optical system 4.

As the optical system 4, there is used a condenser lens operable to converge laser beams exited from the light source units 3 toward the center of the incident surface 51 of the light guide body 5. Namely, the optical system 4 changes (reflects) the optical axis of a laser beam exited from each of the light source units 3 so that the optical axis faces the center of the incident surface 51 of the light guide body 5.

The light guide body 5 is formed to be long, and while the planar incident surface 51 is disposed at one end, and a planar exit surface 52 is disposed at the other end. The light guide body 5 is configured to reflect all light beams on its side surface and thereby propagate the light beams along the longitudinal direction while holding the angles at which the light beams being incident on the incident surface 51 advance.

In this embodiment, the light guide body 5 is an optical fiber constituted of a core as a center core, a clad disposed outside the core and having a refractive index lower than that of the core, and a coating covering the clad (only the core is illustrated). Namely, the incident surface 51 is constituted of a surface on one end side of the core. The light guide body 5 is not limited to an optical fiber and may be, for example, a rod integrator.

As shown in FIGS. 2 to 4, the light source units 3 are divided into laser light source groups 6. In this embodiment, the light source units 3 are divided into two groups, that is, a first laser light source group 6a and a second laser light source group 6b. In each of the laser light source groups 6a and 6b, the same number (twelve) of the light source units 3 are divided.

The first laser light source group 6a is provided with a plurality of (twelve) first light source units 3a from which laser beams L3a exit toward an outer position in the optical incident surface 41 of the optical system 4. The second laser light source group 6b is provided with a plurality of (eight) second light source units 3b from which laser beams L3b exit toward an inner position in the optical incident surface 41 of the optical system 4 with respect to the first light source units 3a and a plurality of (four) third light source units 3c from which laser beams L3c exit toward an inner position in the optical incident surface 41 of the optical system 4 with respect to the second light source units 3b.

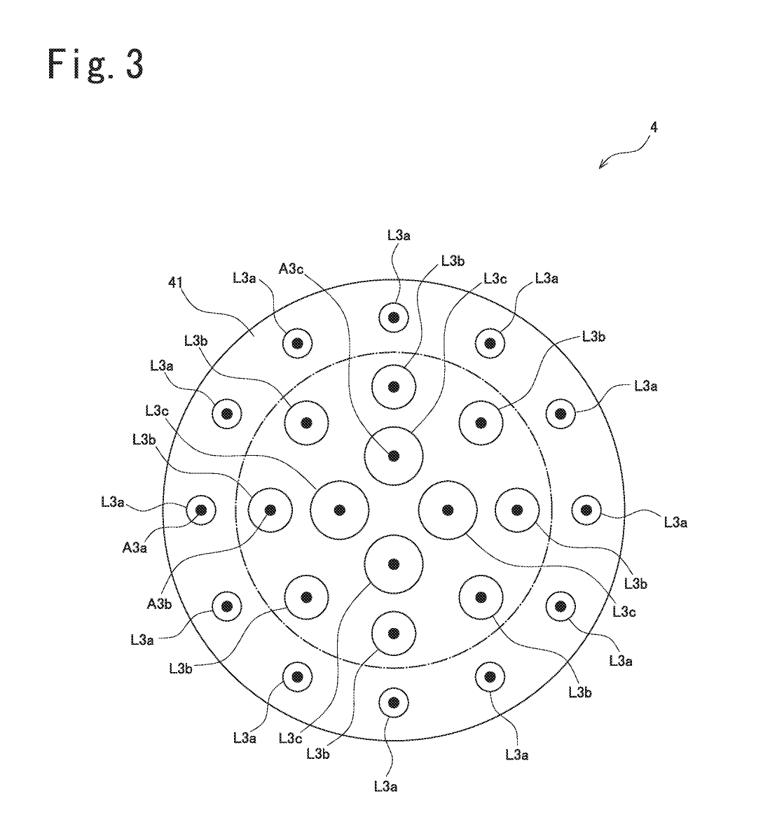

In this embodiment, the optical system 4 converges the laser beams L3a to L3c from the light source units 3a to 3c toward the center of the incident surface 51 of the light guide body 5. Consequently, as the incident positions of the laser beams L3a to L3c to the optical incident surface 41 of the optical system 4 are away from the center of the optical incident surface 41, incident angles θ1 to θ3 of optical axes A3a to A3c of the laser beams L3a to L3c to the incident surface 51 of the light guide body 5 increase. FIG. 3 shows the incident positions and beam diameters of the laser beams L3a to L3c to the optical incident surface 41 of the optical system 4.

Accordingly, the first incident angle θ1 at which the optical axis A3a of the laser beam L3a exited from the first light source unit 3a is incident on the incident surface 51 of the light guide body 5 is larger than the second incident angle θ2 at which the optical axis A3b of the laser beam L3b exited from the second light source unit 3b is incident on the incident surface 51 of the light guide body 5. The second incident angle θ2 is larger than the third incident angle θ3 at which the optical axis A3c of the laser beam L3c from the third light source unit 3c is incident on the incident surface 51 of the light guide body 5.

According to the above constitution, the incident angle θ1 of the optical axis A3a of the laser beam L3a in the first laser light source group 6a is larger than the incident angles θ2 and θ3 of the optical axes A3b and A3c of the laser beams L3b and L3c in the second laser light source group 6b. Accordingly, the light source units 3 are divided into the laser light source groups 6a and 6b for each magnitude of the incident angles θ1 to θ3 at which the optical axes A3a to A3c of the laser beams L3a to L3c are incident on the incident surface 51 of the light guide body 5.

Here, the divergence angles of the laser beams L3a to L3c exited from the respective light source units 3a to 3c can be changed depending on a spacing between the semiconductor laser 31 and the collimate lens 32. The “divergence angle” refers to the fact that in diverging light, among points at which an optical power density is e⁻² (=0.1353) to a maximum value in a beam cross section, an angle formed by light beam passing through the outermost point and the optical axis is half of the “divergence angle”. Meanwhile, the “convergence angle” refers to the fact that in converging light, among points at which an optical power density is e⁻² (=0.1353) to a maximum value in a beam cross section, an angle formed by light beam passing through the outermost point and the optical axis is half of the “convergence angle”. When the cross-sectional shape of beam is not isotropic (true circle shape) but elliptical, the divergence angle or the convergence angle of the laser beam is an average value of the divergence angle or the convergence angle of each elliptical axis.

The divergence angle formed when the laser beam L3a exited from the first light source unit 3a is incident on the optical system 4 is smaller than the divergence angle formed when the laser beam L3b exited from the second light source unit 3b is incident on the optical system 4. The divergence angle formed when the laser beam L3b exited from the second light source unit 3b is incident on the optical system 4 is smaller than the divergence angle formed when the laser beam L3c exited from the third light source unit 3c is incident on the optical system 4.

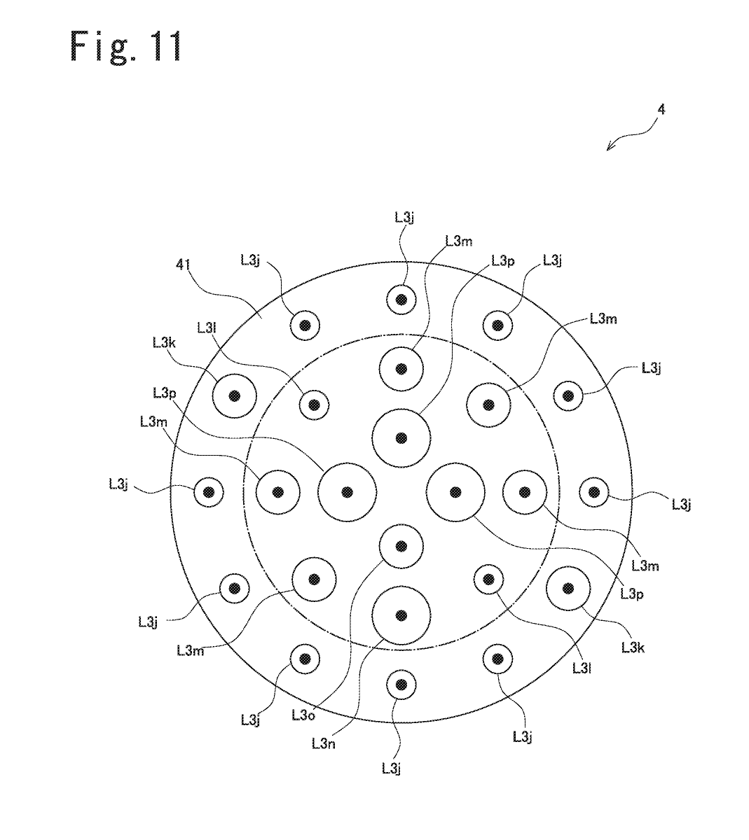

In this embodiment, since the light source units 3a to 3c are disposed such that the distances from the optical system 4 are substantially equal to each other, the divergence angles formed when the laser beams L3a to L3c exited from the respective light source units 3a to 3c are incident on the optical system 4 are proportional to a beam diameter obtained when the laser beams are incident on the optical system 4. Accordingly, FIG. 3 (this similarly applies to FIGS. 10 and 11) shows that the divergence angles of the laser beams L3a to L3c incident on the optical system 4 are reduced in the order from the smallest beam diameter.

In this embodiment, the optical system 4 converges the laser beams L3a to L3c from the light source units 3a to 3c toward the center of the incident surface 51 of the light guide body 5. Specifically, the optical system 4 converges the laser beams L3a to L3c so that the incident surface 51 of the light guide body 5 is located near a condensing point of each of the laser beams L3a to L3c. Consequently, the divergence angles formed when the laser beams L3a to L3c exited from the respective light source units 3a to 3c are incident on the optical system 4 are proportional to the convergence angles (or the divergence angles) formed when the laser beams L3a to L3c are incident on the incident surface 51 of the light guide body 5.

Accordingly, the convergence angle (or the divergence angle) of the laser beam L3a from the first light source unit 3a formed when the laser beam is incident on the incident surface 51 of the light guide body 5 is smaller than the convergence angle (or the divergence angle) of the laser beam L3b from the second light source unit 3b formed when the laser beam is incident on the incident surface 51 of the light guide body 5. Meanwhile, the convergence angle (or the divergence angle) of the laser beam L3b from the second light source unit 3b formed when the laser beam is incident on the incident surface 51 of the light guide body 5 is smaller than the convergence angle (or the divergence angle) of the laser beam L3c from the third light source unit 3c formed when the laser beam is incident on the incident surface 51 of the light guide body 5.

As described above, as the incident angles θ1 to θ3 of the optical axes A3a to A3c of the laser beams L3a to L3c exited from the light source units 3a to 3c are larger, the convergence angles (or the divergence angles) of the laser beams L3a to L3c formed when the laser beams are incident on the incident surface 51 of the light guide body 5 become smaller. Accordingly, the convergence angle (or the divergence angle) of the laser beam L3a from the first laser light source group 6a formed when the laser beam is incident on the incident surface 51 of the light guide body 5 is smaller than the convergence angles (or the divergence angles) of the laser beams L3b and L3c from the second laser light source group 6b formed when the laser beams are incident on the incident surface 51 of the light guide body 5.

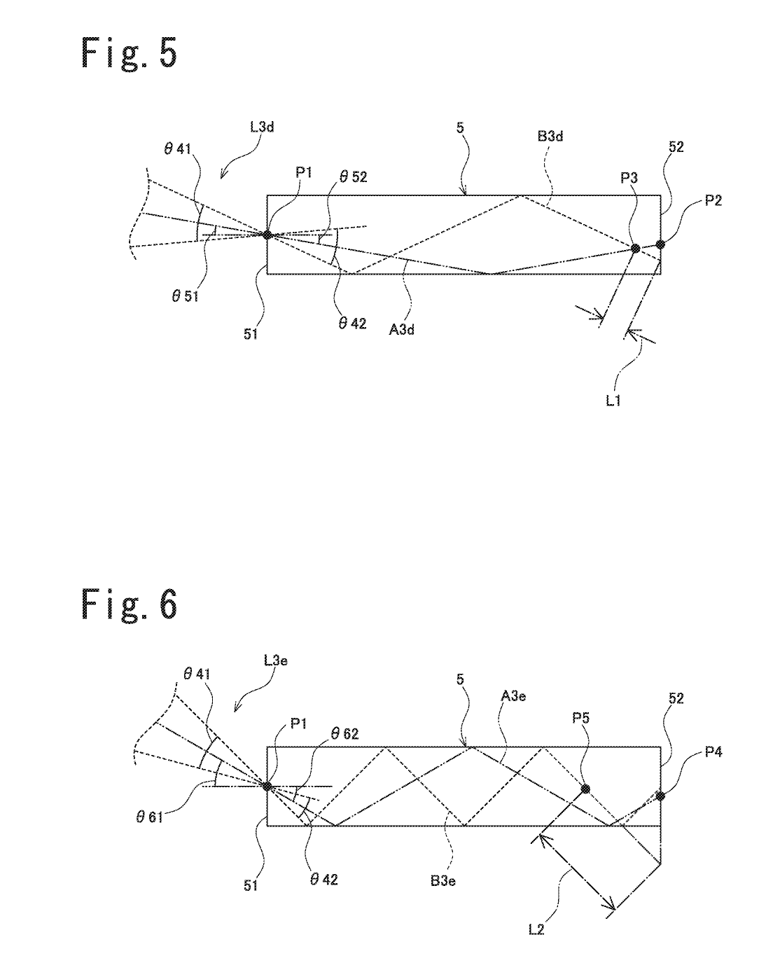

Next, a relationship between the incident angle of a laser beam to the incident surface 51 of the light guide body 5 and an optical path length in the light guide body 5 in the laser beam will be described with reference to FIGS. 5 and 6.

As shown in FIG. 5, a first laser beam L3d converged at a convergence angle θ41 is incident at an incident angle θ51 on the incident surface 51 of the light guide body 5 and diverges in the light guide body 5 at a refraction angle θ52 and a divergence angle θ42. When a refractive index of air is n1 and a refractive index of the light guide body 5 is n2, θ42=(n1/n2)×θ41 and θ52=(n1/n2)×θ51. For ease of understanding, FIG. 5 shows that n1=n2, that is, θ41=θ42 and θ51=θ52.

In the first laser beam L3d, an optical path in a portion of an optical axis A3d (a two-dot chain line in FIG. 5) differs from an optical path in a portion of an outside B3d (a dashed line in FIG. 5). For example, when the portion of the optical axis A3d goes from the incident surface 51 to an exit surface 52, an optical path length difference L1 is generated between the optical path in the portion of the optical axis A3d and the optical path in the portion of the outside B3d. FIG. 5 shows that when the portion of the optical axis A3d goes from a point P1 of the incident surface 51 to a point P2 of the exit surface 52, the portion of the outside B3d goes from the point P1 of the incident surface 51 to a point P3 inside the light guide body 5.

On the other hand, as shown in FIG. 6, a second laser beam L3e is converged at the convergence angle θ41 as in the first laser beam L3d and is incident at an incident angle θ61, which is larger than the incident angle θ51 of the first laser beam L3d, on the incident surface 51 of the light guide body 5. The second laser beam L3e diverges in the light guide body 5 at a refraction angle θ62, which is larger than the refraction angle θ52 of the first laser beam L3d, and at the divergence angle θ42 which is the same as the divergence angle θ42 of the first laser beam L3d. Similarly to FIG. 5, FIG. 6 shows that n1 (the refractive index of air)=n2 (the refractive index of the light guide body 5), that is, θ41=θ42 and θ61=θ62.

In the second laser beam L3e, when a portion of an optical axis A3e goes from the incident surface 51 to the exit surface 52, an optical path length difference L2 is generated between an optical path in the portion of the optical axis A3e (a two-dot chain line in FIG. 6) and an optical path in a portion of an outside B3e (a dashed line in FIG. 6). FIG. 6 shows that when the portion of the optical axis A3e goes from the point P1 of the incident surface 51 to a point P4 of the exit surface 52, the portion of the outside B3e goes from the point P1 of the incident surface 51 to a point P5 inside the light guide body 5.

In the above case, the optical path length in the light guide body 5 in the second laser beam L3e is longer than the optical path length in the light guide body 5 in the first laser beam L3d. Accordingly, in the first and second laser beams L3d and L3e in which the divergence angle θ42 (or the convergence angle θ41) is the same, the optical path length difference L2 in the second laser beam L3e is longer than the optical path length difference L1 in the first laser beam L3d.

Namely, since the optical path length in the light guide body 5 increases as the incident angle of a laser beam is larger, in diverging (or converging) laser beam, an optical path length difference between an optical axis portion and another portion increases. Accordingly, since coherence is lowered as the incident angle of a laser beam is larger, speckle noise is less likely to occur.

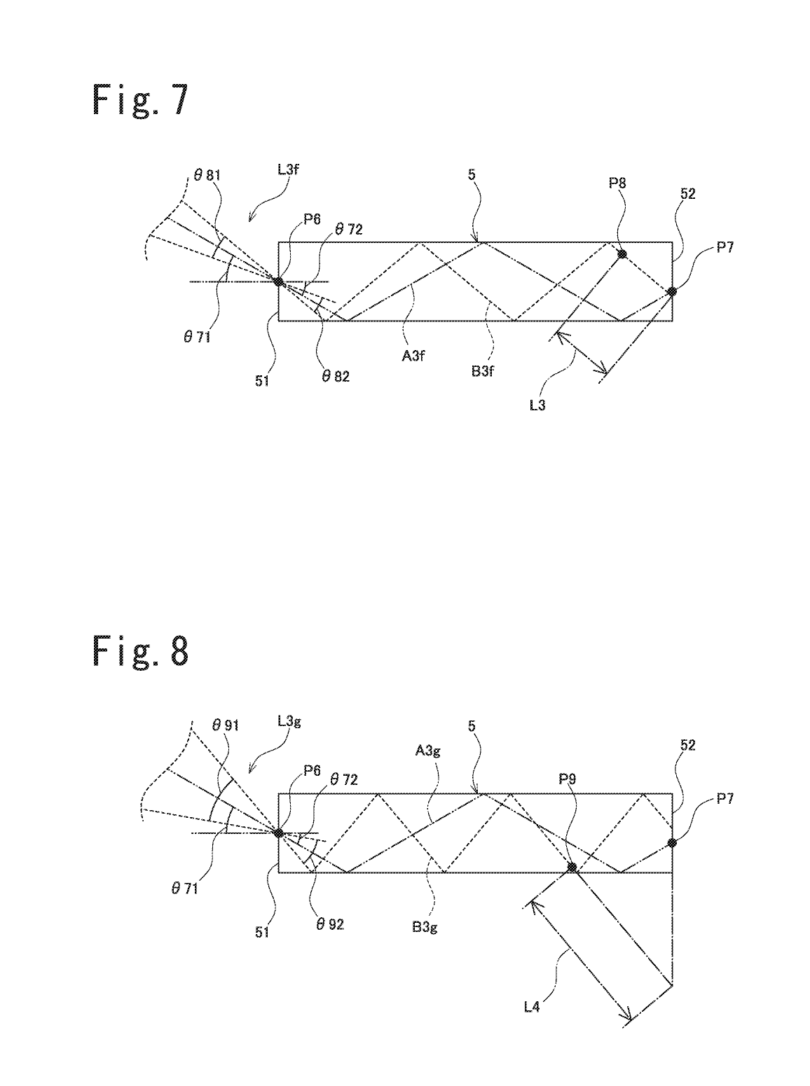

Next, a relationship between the convergence angle (or the divergence angle) of a laser beam formed when the laser beam is incident on the incident surface 51 of the light guide body 5 and the optical path length in the light guide body 5 in the laser beam will be described with reference to FIGS. 7 and 8.

As shown in FIG. 7, a first laser beam L3f incident at an incident angle θ71 on the incident surface 51 of the light guide body 5 is converged at a convergence angle θ81 and diverges in the light guide body 5 at a refraction angle θ72 and a divergence angle θ82. Similarly to FIGS. 5 and 6, FIG. 7 shows that n1 (the refractive index of air)=n2 (the refractive index of the light guide body 5), that is, θ71=θ72 and θ81=θ82.

In the first laser beam L3f, an optical path in a portion of an optical axis A3f (a two-dot chain line in FIG. 7) differs from an optical path in a portion of an outside B3f (a dashed line in FIG. 7). For example, when the portion of the optical axis A3f goes from the incident surface 51 to the exit surface 52, an optical path length difference L3 is generated between the optical path in the portion of the optical axis A3f and the optical path in the portion of the outside B3f. FIG. 7 shows that when the portion of the optical axis A3f goes from a point 64 of the incident surface 51 to a point 75 of the exit surface 52, the portion of the outside B3f goes from a point P6 of the incident surface 51 to a point P8 inside the light guide body 5.

On the other hand, as shown in FIG. 8, a second laser beam L3g is incident on the incident surface 51 of the light guide body 5 at the incident angle θ71 as in the first laser beam L3f and is converged at a convergence angle θ91 which is larger than the convergence angle θ81 of the first laser beam L3f. The second laser beam L3g diverges in the light guide body 5 at the refraction angle θ72, which is the same as the refraction angle θ72 of the first laser beam L3f, and at a divergence angle θ92 which is larger than the divergence angle θ82 of the first laser beam L3f. Similarly to FIGS. 5 to 7, FIG. 8 shows that n1 (the refractive index of air)=n2 (the refractive index of the light guide body 5), that is, θ71=θ72 and θ91=θ92.

In the second laser beam L3g, when a portion of an optical axis A3g goes from the incident surface 51 to the exit surface 52, an optical path length difference L4 is generated between an optical path in the portion of the optical axis A3g (a two-dot chain line in FIG. 8) and an optical path in a portion of an outside B3g (a dashed line in FIG. 8). FIG. 8 shows that when the portion of the optical axis A3g goes from the point P6 of the incident surface 51 to a point P7 of the exit surface 52, the portion of the outside B3g goes from the point P6 of the incident surface 51 to a point P9 inside the light guide body 5.

In the above case, the optical path length of the portion of the optical axis A3g in the second laser beam L3g is the same as the optical path length of the portion of the optical axis A3f in the first laser beam L3f. On the other hand, the optical path length of the portion of the outside B3g in the second laser beam L3g is longer than the optical path length of the portion of the outside B3f in the first laser beam L3f. Accordingly, in the first and second laser beams L3f and L3g having the same incident angle θ71 (or the same refraction angle θ72), the optical path length difference L4 in the second laser beam L3g is longer than the optical path length difference L3 in the first laser beam L3f.

Namely, as the convergence angle (or the divergence angle) of a laser beam formed when the laser beam is incident on the incident surface 51 of the light guide body 5 is larger, an optical path length difference between an optical axis portion in the laser beam and another portion increases. Accordingly, since the coherence is lowered as the convergence angle (or the divergence angle) of a laser beam is larger when the laser beam is incident on the incident surface 51 of the light guide body 5, the speckle noise is less likely to occur.

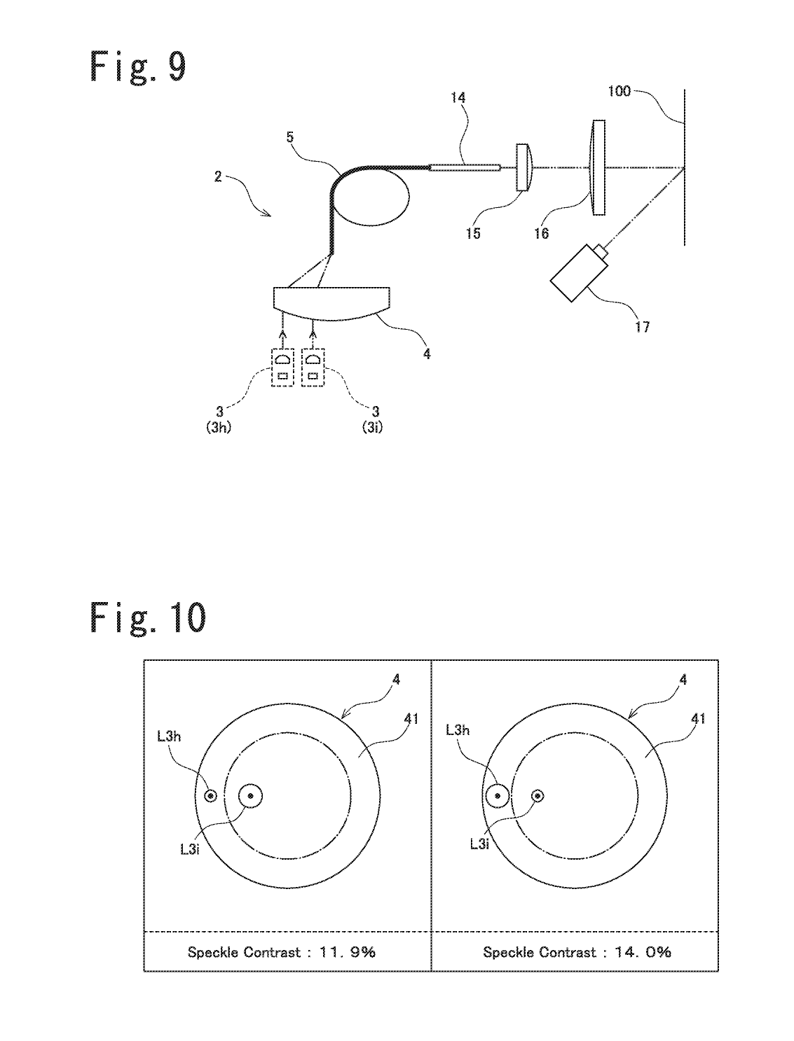

Next, advantages of the laser light source device 2 according to this embodiment will be verified with reference to FIGS. 9 and 10. FIG. 10 shows the incident position and beam diameter of each light to the optical incident surface 41 of the optical system 4, similarly to FIG. 3.

In order to verify the advantages, as shown in FIG. 9, light exited from the laser light source device 2 is made incident on a rod integrator 14 and projection lenses 15 and 16 in an order named, and an end face image of the rod integrator 14 is projected on the screen 100 while being magnified about 100 times. The screen 100 is then photographed by a CCD camera 17 to measure speckle contrast from the image projected on the screen 100.

The speckle contrast is a value obtained by dividing a standard deviation of light intensity in each pixel of the CCD camera 17 by an average value of the light intensity in each pixel. Also, the speckle contrast is an index in which as it is larger, a fluctuation of light intensity (speckle noise) becomes large.

As shown in FIG. 10, there will be considered the case where a first laser beam L3h is away from the center of the optical incident surface 41 of the optical system 4 with respect to a second laser beam L3i. Namely, there will be considered the case where the incident angle (20°) of the first laser beam L3h is larger than the incident angle (10°) of the second laser beam L3i.

First, in the case where the convergence angle (10°) of the first laser beam L3h formed when the laser beam was incident on the incident surface 51 of the light guide body 5 was smaller than the convergence angle (20°) of the second laser beam L3i formed when the laser beam was incident on the incident surface 51 of the light guide body 5, the speckle contrast was 11.9%. On the other hand, in the case where the convergence angle (20°) of the first laser beam L3h formed when the laser beam was incident on the incident surface 51 of the light guide body 5 was larger than the convergence angle (10°) of the second laser beam L3i formed when the laser beam was incident on the incident surface 51 of the light guide body 5, the speckle contrast was 14.0%.

Consequently, it was possible to verify that in a laser beam in which the convergence angle (or divergence angle) is smaller when the laser beam is incident on the incident surface 51 of the light guide body 5, the speckle noise is further lowered by increasing the incident angle.

Based on the above, according to the image projection device 1 and the laser light source device 2 according to this embodiment, the laser light source groups 6a and 6b are provided with the light source units 3a to 3c from which the laser beams L3a to L3c exit toward the incident surface 51 of the light guide body 5. The laser light source groups 6a and 6b are divided for each magnitude of the incident angles θ1 to θ3 to the incident surface 51 of the optical axes A3a to A3c of the laser beams L3a to L3c exited from the light source units 3a to 3c.

Since the optical path length in the light guide body 5 becomes longer as the incident angles θ1 to θ3 of the laser beams L3a to L3c are larger, in the diverging laser beams L3a to L3c, the optical path length difference between the optical axis portion and another portion increases, for example. In the same incident angle, as the convergence angles or the divergence angles of the laser beams L3a to L3c are larger when the laser beams are incident on the incident surface 51 of the light guide body 5, in the laser beams L3a to L3c, the optical path length difference between the optical axis portion and another portion increases, for example.

As described above, in the laser beams L3a to L3c, when the optical path difference between the optical axis portion and another portion increases, the coherence is lowered. Consequently, the speckle noise is reduced. Thus, in the laser light source device 2 according to the present invention, as the incident angles θ1 to θ3 of the laser beams L3a to L3c from the laser light source groups 6a and 6b are larger, the average value of the convergence angle and/or the divergence angle of the laser beams L3a to L3c in the laser light source groups 6a and 6b becomes smaller when the laser beams are incident on the incident surface 51 of the light guide body 5.

According to the above constitution, also in the laser beam L3a in which the convergence angle or the divergence angle is small, since the optical path length is increased by increasing the incident angle θ1, the optical path length difference between the optical axis portion and another portion in the laser beam L3a is ensured, for example. Accordingly, since the coherence of a laser beam in the entire device is lowered, the speckle noise in the entire device is reduced.

According to the image projection device 1 and the laser light source device 2, as the incident angles θ1 to θ3 of the laser beams L3a to L3c from the light source units 3a to 3c are larger, the convergence angles or the divergence angles of the laser beams L3a to L3c in the light source units 3a to 3c become smaller when the laser beams are incident on the incident surface 51 of the light guide body 5. Namely, as the convergence angles or divergence angles of the laser beams L3a to L3c are smaller, the incident angles θ1 to θ3 of the laser beams L3a to L3c become larger. Accordingly, since the coherence of a laser beam in the entire device is effectively lowered, the speckle noise in the entire device is effectively reduced.

The present invention is not limited to the configuration of the aforementioned embodiment and the aforementioned advantages. In this invention, it goes without saying that various changes and modifications may be made without departing from the spirit and scope of the invention. For example, it also goes without saying that the configuration and methods of the following various modified examples may be arbitrarily selected and adopted into the configuration and methods of the aforementioned embodiment.

In the laser light source device 2 according to the above embodiment, as the incident angles θ1 to θ3 of the laser beams L3a to L3c from the light source units 3a to 3c are larger, the convergence angles or the divergence angles of the laser beams L3a to L3c in the laser light source units 3a to 3c become smaller when the laser beams are incident on the incident surface 51 of the light guide body 5. However, the laser light source device 2 according to the present invention is not limited to such a configuration.

For example, in the laser light source device 2 according to the present invention, as shown in FIG. 11, in some of laser beams, the laser beams having a larger incident angle may have a larger convergence angle or divergence angle when the laser beams are incident on the incident surface 51. In the laser light source device 2 of FIG. 11, as the laser beams of the first laser light source group, there are first and second laser beams L3j and L3k, and as the laser beams of the second laser light source group, there are third to seventh laser beams L3l to L3p.

The incident angles of the first and second laser beams L3j and L3k to the incident surface 51 of the light guide body 5 are the same, the incident angles of the third to fifth laser beams L3l, L3m, and L3n to the incident surface 51 of the light guide body 5 are the same, and the incident angles of the sixth and seventh laser beams L3o and L3p to the incident surface 51 of the light guide body 5 are the same. The incident angles of the first and second laser beams L3j and L3k are larger than the incident angles of the third to fifth laser beams L3l, L3m, and L3n, and the incident angles of the third to fifth laser beams L3l, L3m, and L3n are larger than the incident angles of the sixth and seventh laser beams L3o and L3p.

The convergence angles (or the divergence angles) of the first and third laser beams L3j and L3l formed when the laser beams are incident on the incident surface 51 of the light guide body 5 are the same, the convergence angles (or the divergence angles) of the second, fourth, and sixth laser beams L3k, L3m, and L3o formed when the laser beams are incident on the incident surface 51 of the light guide body 5 are the same, and the convergence angles (or the divergence angles) of the fifth and seventh laser beams L3n and L3p formed when the laser beams are incident on the incident surface 51 of the light guide body 5 are the same. The convergence angles (or the divergence angles) of the first and third laser beams L3j and L3l are smaller than the convergence angles (or the divergence angles) of the second, fourth, and sixth laser beams L3k, L3m, and L3o, and the convergence angles (or the divergence angles) of the second, fourth, and sixth laser beams L3k, L3m, and L3o are smaller than the convergence angles (or the divergence angles) of the fifth and seventh laser beams L3n and L3p.

According to the laser light source device 2 of FIG. 11, in the laser beams L3j and L3k from the first laser light source group, the incident angles are larger than the incident angles of the laser beams L3l to L3p from the second laser light source group, and the average value of the convergence angles (or the divergence angles) is small when the laser beams L3j and L3k are incident on the incident surface 51 of the light guide body 5. In short, the laser light source device 2 according to the present invention may be configured such that as the incident angles of laser beams from the laser light source group 6 are larger, the average value of the convergence angles or the divergence angles of the laser beams in the laser light source group 6 becomes smaller when the laser beams are incident on the incident surface 51 of the light guide body 5.

In the laser light source device 2 according to the above embodiment, the light source units 3 are divided into the laser light source groups 6a and 6b for each magnitude of the incident angles so that the same number of the light source units 3 are divided, and namely, the light source units 3 are divided based on the number of the light source units 3 (the laser beams L3a to L3c). However, the laser light source device according to the present invention is not limited to such a configuration.

For example, the laser light source device according to the present invention may be configured such that the light source units 3 are divided into laser light source groups for each magnitude of the incident angles based on angles or solid angles divided equally. In short, the laser light source device according to the present invention may be configured such that the light source units 3 are divided into the laser light source groups for each magnitude of the incident angles.

The laser light source device 2 according to the above embodiment is provided with the two laser light source groups 6a and 6b. However, the laser light source device according to the present invention is not limited to such a configuration. For example, the laser light source device according to the present invention may be provided with three or more laser light source groups 6.

Further, in the laser light source device 2 according to the above embodiment, the light source unit 3 is provided with the collimate lens 32. However, the laser light source device according to the present invention is not limited to such a configuration. For example, the laser light source device according to the present invention may be configured such that the light source unit 3 is not provided with the collimate lens 32 and is an external resonator semiconductor laser. In such a configuration, when a laser beam is exited from the light source unit 3 to be incident on the optical system 4, the divergence angle of the laser beam can be changed by changing a resonator length of an external resonator.

Further, the laser light source device 2 according to the above embodiment is configured to be provided with the optical system 4. However, the laser light source device according to the present invention is not limited to this configuration. For example, the laser light source device according to this invention may be configured that the optical system 4 is not provided and a laser light exited from the laser light source 3 directly is incident on the incident surface 51 of the light guide body 5.

Further, in the laser light source device 2 according to the above embodiment, the divergence angles of the laser beams L3a to L3c exited from the respective light source units 3a to 3c are proportional to the convergence angles (or the divergence angles) of the laser beams L3a to L3c formed when the laser beams are incident on the incident surface 51 of the light guide body 5. However, the laser light source device according to the present invention is not limited to such a configuration. For example, the laser light source device according to the present invention may be configured such that when the light source units 3a to 3c are incident on different optical systems 4, the divergence angles of the laser beams L3a to L3c exited from the respective light source units 3a to 3c are not proportional to the convergence angles (or the divergence angles) of the laser beams L3a to L3c formed when the laser beams are incident on the incident surface 51 of the light guide body 5.

In the laser light source device 2 according to the above embodiment, since, in the light source units 3a to 3c, the distances from the optical system 4 are substantially equal to each other, the divergence angles formed when the laser beams L3a to L3c exited from the respective light source units 3a to 3c are incident on the optical system 4 are proportional to the beam diameter obtained when the laser beams are incident on the optical system 4. However, the laser light source device according to the present invention is not limited to such a configuration. For example, the laser light source device according to the present invention may be configured such that the divergence angle formed when the laser beam L3 exited from each of the light source units 3 is incident on the optical system 4 is not proportional to the beam diameter obtained when the laser beam is incident on the optical system 4, since the distances between each of the light source units 3 and the optical system 4 are different.

Further, the laser light source device 2 according to the above embodiment is configured to be used in the image projection device 1. However, the laser light source device 2 according to the present invention is not limited to this configuration. For example, the laser light source device 2 according to this invention may be configured to be used in an exposure device which performs exposure using laser light.

The image projection device 1 according to the above embodiment is provided with the three laser light source devices 2R, 2G, and 2B. However, the image projection device according to the present invention is not limited to such a configuration. For example, the image projection device according to the present invention may be provided with one laser light source device 2, two laser light source devices 2, or four or more laser light source devices 2.

Furthermore, the laser light source device 2 according to the above embodiment is configured to be provided with the light guide body 5. However, the laser light source device according to the present invention is not limited to this configuration. For example, the laser light source device according to this invention may be configured that the light guide body 5 itself is not provided, and a connecting portion removably connecting the light guide body 5 is provided.

### DESCRIPTION OF REFERENCE SINGS

1 . . . image projection device
2 . . . laser light source device
3, 3a, 3b, 3c . . . light source unit
4 . . . optical system
5 . . . light guide body
6, 6a, 6b . . . laser light source group
11 . . . light source side optical system
11a . . . integrator optical system
11b . . . reflection mirror
12 . . . image optical system
12a . . . space modulation element
12b . . . total reflection prism
12c . . . dichroic prism
13 . . . projection optical system
14 . . . rod integrator
15, 16 . . . projection lens
17 . . . CCD camera
31 . . . semiconductor laser
32 . . . collimate lens
41 . . . optical incident surface
51 . . . incident surface
52 . . . exit surface
100 . . . screen

1. A laser light source device, comprising:
a plurality of light source units from which laser beams exit; and
a light guide body having an incident surface on which the laser beams exited from the plurality of light source units are incident,
wherein the plurality of light source units are divided into a plurality of laser light source groups based on magnitudes of angles at which optical axes of the laser beams are incident on the incident surface; and
as the incident angles of the laser beams from the laser light source group are larger, an average value of convergence angle and/or divergence angle of the laser beams in the laser light source group becomes smaller when the laser beams are incident on the incident surface.

2. A laser light source device, comprising:
a plurality of light source units from which laser beams exit; and
an optical system on which the laser beams exited from the plurality of light source units are incident and which exits the laser beams toward an incident surface of a light guide body,
wherein the plurality of light source units are divided into a plurality of laser light source groups based on magnitudes of angles at which optical axes of the laser beams are incident on the incident surface; and
the light source unit and the optical system are configured such that as the incident angles of the laser beams from the laser light source group are larger, an average value of convergence angle and/or divergence angle of the laser beams in the laser light source group becomes smaller when the laser beams are incident on the incident surface.

3. The laser light source device according to claim 1, wherein as the incident angle of the laser beam from the light source unit is larger, the convergence angle or the divergence angle of the laser beam in the light source unit becomes smaller when the laser beam is incident on the incident surface.

4. An image projection device comprising at least one laser light source device according to claim 1 and using a light beam exited from the laser light source device as projection light.

5. The laser light source device according to claim 2, wherein as the incident angle of the laser beam from the light source unit is larger, the convergence angle or the divergence angle of the laser beam in the light source unit becomes smaller when the laser beam is incident on the incident surface.

6. An image projection device comprising at least one laser light source device according to claim 2 and using a light beam exited from the laser light source device as projection light.
